(19) United States
(12) Patent Application Publication
(10) Pub. No.: US 2005/0115492 A1
(43) Pub. Date: Jun. 2, 2005

(54) Method and apparatus of the chemical metal organic vapor epitaxy for the multi-chamber epitaxy layer deposition

(76) Inventors: Chia-Cheng Liu, Tucheng City (TW); Chiung-Yu Chang, Tucheng City (TW); Tung-Hung Tsai, Tucheng City (TW); Shun-Yi Hsu, Tucheng City (TW); Chiu-Ming Peng, Tucheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/722,522

(22) Filed: Nov. 28, 2003

(51) Int. Cl. C30B 23/00; C30B 25/00; C30B 28/12; C30B 28/14

(52) U.S. Cl. 117/86

(57) ABSTRACT

A method and the apparatus of the chemical metal organic vapor epitaxy for the multi-chamber epitaxy layer deposition can process many epitaxy reactions of the organic light-emitting diodes at the same time. More, the different types of epitaxy layers can individual react while passing through the adjustment of time periods. By using the multiple organic light-emitting diodes, it can form multiple epitaxy layers with varying types at the same time. Therefore, it achieves the purpose of shortening the manufacturing process.

### BACKGROUND OF THE INVENTION

1. Field of the Invention

The present invention is to provide a method and an apparatus of the chemical metal organic vapor epitaxy for the multiple-chamber epitaxy layer deposition. More particularly, the present invention is used to produce a LED component for the method and the apparatus of the chemical metal organic vapor epitaxy in the multiple-chamber epitaxy layer deposition. By using the method and the apparatus of the chemical metal organic vapor epitaxy for the multi-chamber epitaxy layer deposition, it can fast implement LED component thereto shortens the manufacturing time.

2. Description of the Prior Art

The structure of LED component mainly comprises: a substrate; an epitaxy layer, an epitaxy layer comprising a N-type epitaxy layer; an active area and a P-type epitaxy. The substrate can be a sapphire substrate, and the epitaxy generally can be GaN. More, they mostly are formed on the substrate by using chemical vapor phase epitaxy.

The method of chemical vapor phase epitaxy used in the conventional technique requires to be implemented in the same reaction chamber. Therefore, the epitaxy layers with different types in the epitaxy process need to grow in order and the consumption time will grow accumulatively. For example, the required time for growing N-type epitaxy layer needs fours hours, and the required time for growing P-type epitaxy layer needs one hour. If the substrate needs to contain a N-type epitaxy layer and a P-type epitaxy layer, then, it needs to take four hours for its reaction time.

According to the above description, the present invention is to provide a method and an apparatus of the chemical organic vapor epitaxy for the multi-chamber epitaxy layer deposition. By using an apparatus of the chemical metal organic vapor epitaxy for the multi-chamber epitaxy layer deposition with multiple reaction conditions, it can make multiple epitaxy layers individually react by period adjustment thereto shorten the manufacturing time.

### SUMMARY OF THE INVENTION

The present invention is to provide an apparatus of the chemical metal organic vapor epitaxy for the multiple-chamber epitaxy layer deposition. The main feature of the present invention is that the apparatus of the chemical metal organic vapor epitaxy for the multi-chamber epitaxy layer deposition is with multiple chambers. The multiple chambers are with multiple reaction conditions. Further, it can make multiple LED components form multiple epitaxy layers thereto shorten the manufacturing time.

Another purpose of the present invention is to provide a method of the chemical metal organic vapor epitaxy for the multi-chamber epitaxy layer deposition. By using the method and of the chemical metal organic vapor epitaxy for the multi-chamber epitaxy layer deposition, it can implement multiple LED components and make different types of epitaxy layers individually react by period adjustment at the same time. Further, it can make different types of LED components form different types of multiple epitaxy layers thereto shorten the manufacturing time.

For a more complete understanding of the present invention and for further advantages thereof, reference is now made to the following description taken in conjunction with the accompanying drawing, in which:

### BRIEF DESCRIPTION OF THE DRAWINGS

FIG. 1 is one of the preferred embodiments according to the present invention showing the apparatus of the metal organic chamber vapor epitaxy for the multi-chamber epitaxy layer deposition; and

FIG. 2 is one of the preferred embodiments according to the present invention showing the flow chart of the metal organic chamber vapor epitaxy for the multi-chamber epitaxy layer deposition.

### DETAILED DESCRIPTION OF THE PREFERRED EMBODIMENTS

The present invention is to provide an apparatus of the chemical metal organic vapor epitaxy for the multi-chamber epitaxy layer deposition. The apparatus is used to produce a LED component, which includes: Multiple chambers, the multiple chambers are arranged along the periphery; Multiple supporting bases, and the supporting bases are used for supporting substrate, and are individually positioned in the chambers; A pick-up apparatus, the apparatus is positioned in the center of the circle and are with at least one robotic arm and one rotated chassis. It uses the rotated chassis to shift the robotic arm, and then uses the robotic arm to pick up the substrate for the change in between the multiple chambers.

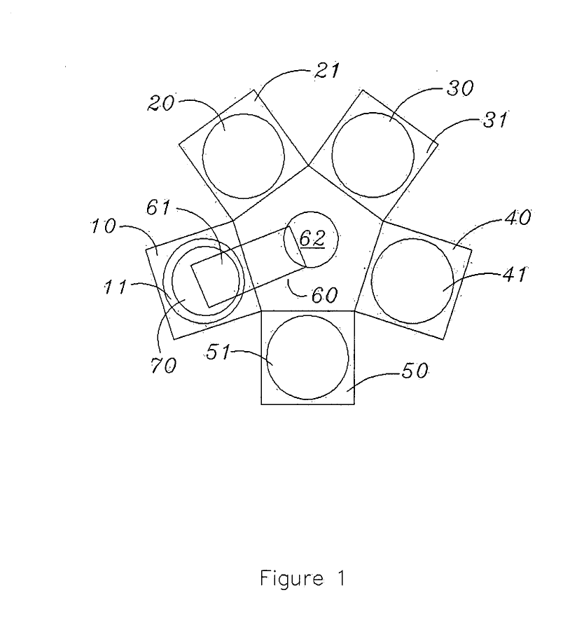

For the description of the preferred embodiment in the present invention, the growth for the epitaxy layer of LED generally requires at least five hours to implement. This may includes four hours in N-type epitaxy layer and one hour in P-type epitaxy layer. In order to shorten the manufacturing time, the present invention uses the reaction period of P-type epitaxy layer as a unit to divide the reaction period of N-type epitaxy layer as four stages. The reaction in each stage uses the chamber of its individual reaction condition to process reaction. Please referring to FIG. 1, it is one of the preferred embodiments according to the present invention showing the apparatus of the metal organic chamber vapor epitaxy for the multi-chamber epitaxy layer deposition. The apparatus comprises: Five chambers 10,20, 30, 40, and 50, and the multiple chambers are arranged along the periphery; Five supporting bases 11, 21, 31, 41, and 51, and the top side of the supporting bases is used for supporting a substrate 70, and the supporting bases are individually positioned in the multiple chambers; A pick-up apparatus 60, and the apparatus 60 is positioned in the center of the circle; And at least a robotic arm 61 and a rotated chassis 62. It uses the rotated chassis 62 to shift the robotic arm 61, and then uses the robotic arm 61 to pick up the substrate. The substrate 70 then can change between the multiple chambers.

Further, the method of the chemical metal organic vapor epitaxy for the multiple-chamber epitaxy layer deposition in the present invention can process multiple epitaxy reactions of the LEDs components at the same time. More, it can make different types of epitaxy layers individually react by period adjustment at the same time. The method comprises: Providing multiple chambers; Forming multiple substrates, and each chamber has its individual reaction condition; Forming multiple substrates, and the multiple substrates are put into different chambers; Forming a first epitaxy layer, and the first epitaxy layer is on the substrate; The substrate is put into a P-type chamber, and the second chamber is removed to the multiple chambers to form the first epitaxy layer of the second substrate; Forming the second epitaxy layer, the second epitaxy layer is on the first epitaxy layer. The substrate is removed from the P-type chamber, and then the second substrate is removed to the P-type chamber for growing the second epitaxy layer of the second substrate. The first epitaxy layer is implemented by in-out processes between the multiple chambers. Also, the reaction time of each chamber is the growth time of the second epitaxy layer. The reaction condition for each chamber at least comprises a carrier gas, a precursor, and a tolerated temperature range. The carrier gas can be H, and the precursor can be one of BC13 and PC13, BC13 and PH13, and NH3.

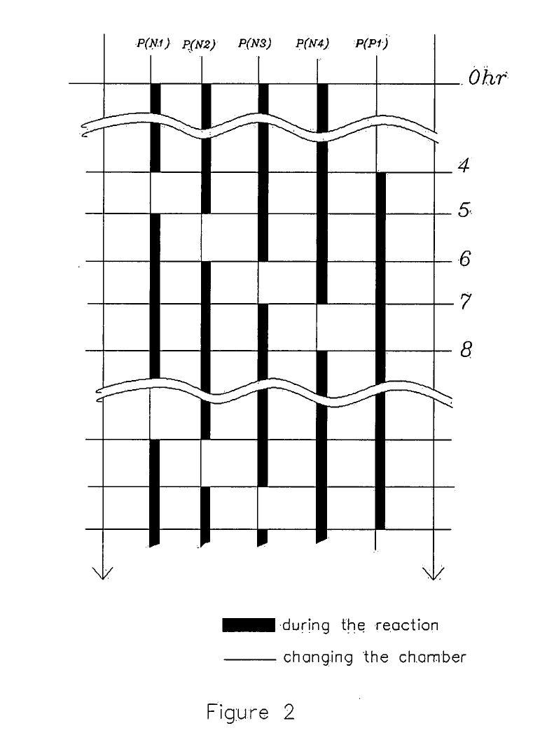

Further description in the method of the chemical metal organic vapor epitaxy for the multi-chamber epitaxy layer deposition can be shown in the present invention, please referring to FIG. 2. It is one of the preferred embodiments according to the present invention showing the flow chart of the metal organic chamber vapor epitaxy for the multi-chamber epitaxy layer deposition. First, it uses the growth time for P-type epitaxy layer as a unit. Then, it divides the reaction time of N-type epitaxy layer as four stages. The reaction of each stage uses the chamber with its individual reaction condition to process reaction, which can divide as: the reaction period for the first chamber PN1, the reaction period for the second chamber PN2, the reaction period for the third chamber PN3, the reaction period for the fourth chamber PN4, and the reaction period for the fifth chamber PP1.

Following the above step, please referring the reaction period of each chamber PN, it forms multiple substrates. Firstly, the first substrate performs reaction for one hour in the first chamber. The first type of the epitaxy layer is formed on the substrate. Then, the substrate is removed from the first chamber and to the second chamber. More, the second substrate is removed to the first chamber. After two hours later, the first type of the first epitaxy layer forms a second type of the first epitaxy layer. Then, the substrate is removed from the second chamber to the third chamber. Further, the second substrate is removed to the second chamber. The second substrate, in the meantime, forms the second type of epitaxy layer on it. Then, it repeats above steps until to the fourth hours. Here at least a substrate can form all the first epitaxy layers, and the first epitaxy layers of another substrates are gradually formed. In the meantime, the substrates with the first epitaxy layers are removed from the chamber, and to the fifth chamber for growing the second epitaxy layer. After that, the substrate with the first epitaxy layer is removed to the fifth chamber every hour for processing the growth of the second epitaxy layer.

In conclusion, the present invention meets novelty, improvement, and is applicable to the industry. It, therefore, meets the essential elements in patentability. There is no doubt that the present invention is legal to apply to the patent, and indeed we hope that this application can be granted as a patent.

Although the present invention has been described in detail with respect to alternate embodiments, various changes and modifications may be suggested to one skilled in the art, and it should be understood that various changes, suggestions, and alternations can be made hereto without departing from the spirit and scope of the invention as defined by the appended claims.

1. A method of the chemical metal organic vapor epitaxy for the multiple-chamber epitaxy layer deposition is used in the epitaxy of LED process, comprising the steps of:
providing multiple chambers, and each of said chambers are with its individual reaction condition;
forming multiple substrates, and said substrates being in different chambers;
forming an epitaxy layer, and said epitaxy layer being on said substrate;
removing said substrate to the P-type chamber, and the second substrate being put into said multiple chambers for forming the epitaxy layer of the second substrate; and
forming a second epitaxy layer, said second epitaxy layer being on the said first epitaxy layer, and said substrate being removed from said P-type chamber after one reaction period, then, the second substrate being put into said P-type chamber for forming the second epitaxy layer of the second substrate, and said first epitaxy layer being implemented by multiple in-out processes in the chambers, Further, the reaction time of each chamber being the growth time for the second epitaxy layer.

2. The method of the chemical metal organic vapor epitaxy for the multi-chamber epitaxy layer deposition according to claim 1, wherein the time of the first epitaxy layer for passing through said multiple chambers is equal to the required reaction time of said first epitaxy layer divide to the required reaction time of said second epitaxy layer, more, it uses the integral of the number.

3. The method of the chemical metal organic vapor epitaxy for the multi-chamber epitaxy layer deposition according to claim 1, wherein said reaction time can be one hour.

4. The method of the chemical metal organic vapor epitaxy for the multi-chamber epitaxy layer deposition according to claim 1, wherein the said first epitaxy layer can be a N-type epitaxy layer.

5. The method of the chemical metal organic vapor epitaxy for the multi-chamber epitaxy layer deposition according to claim 1, wherein said second epitaxy layer can be a P-type epitaxy layer.

6. The method of the chemical metal organic vapor epitaxy for the multi-chamber epitaxy layer deposition according to claim 1, wherein the reaction condition of said chamber includes a carrier gas, a precursor, and a tolerated temperature.

7. The method of the chemical metal organic vapor epitaxy for the multi-chamber epitaxy layer deposition according to claim 1, wherein said carrier gas can be H, and said precursor can be one of BC13 and PC13, BC13 and PH13, and NH3.

8. A method of the chemical metal organic vapor epitaxy for the multi-chamber epitaxy layer deposition is used in the epitaxy of LED process, comprising the steps of:
providing at least five chambers, each of said chambers has its individual reaction condition;
forming multiple substrates, the first substrate being put into the first chamber;
forming the fist type of the first epitaxy layer, said first type of the first epitaxy layer being on said substrate, and after passing one period of reaction time, the substrate beings removed from the said first chamber, and put into the second chamber, and also, the second substrate being removed to said first chamber;
forming the second type of the first epitaxy layer, said second type of the first epitaxy layer being on said first type of the first epitaxy layer, and after passing said reaction time, said substrate being removed from said second chamber, and then put into the third chamber, and then, the second substrate being removed to said second chamber;
forming the third type of the first epitaxy layer, said third type of the first epitaxy layer being on said second type epitaxy layer, and after passing through said reaction time, said substrate being removed from the third chamber, then, put into the fourth chamber, and further, said second substrate being removed to said third chamber;
forming the fourth type of the first epitaxy layer, said fourth type of the first epitaxy layer being positioned on said third type epitaxy layer, and after passing through said reaction time, said substrate being removed from said fourth chamber, and then, removed to the fifth chamber, and further, said second substrate being removed to the said fourth chamber; and
forming the second epitaxy layer, said second epitaxy layer being on said fourth type epitaxy layer, and after passing through said reaction time, said substrate being removed from said fifth chamber, and the second substrate being removed to said fifth chamber, and said reaction time being the growth time of the second epitaxy layer, and said substrate through in-out processing between multiple chambers implementing multiple epitaxy layers of multiple LEDs.

9. The method of the chemical metal organic vapor epitaxy for the multi-chamber epitaxy layer deposition according to claim 8, wherein said reaction time can be one hour.

10. The method of the chemical metal organic vapor epitaxy for the multi-chamber epitaxy layer deposition according to claim 8, wherein said first epitaxy layer can be N-type epitaxy layer.

11. The method of the chemical metal organic vapor epitaxy for the multi-chamber epitaxy layer deposition according to claim 8, wherein said second epitaxy layer can be a P-type epitaxy layer.

12. The method of the chemical metal organic vapor epitaxy for the multi-chamber epitaxy layer deposition according to claim 8, wherein the reaction condition of said chamber at least includes a carrier gas, a precursor, and a tolerated temperature range.

13. The method of the chemical metal organic vapor epitaxy for the multi-chamber epitaxy layer deposition according to claim 12, wherein said carrier gas can be H, and said precursor can be one of BC13 and PC13, BC13 and PH13, and NH3.

14. An apparatus of the chemical organic vapor epitaxy for the multi-chamber epitaxy layer deposition is used in the epitaxy layer of the LED process, comprising;
multiple chambers, which said multiple chambers are arranged along the periphery;
multiple supporting bases, which said supporting bases is used for supporting a substrate, and said supporting substrates are individually positioned in said multiple chambers; and
a pick-up apparatus, said pick-up apparatus being positioned in the center of the said circle, and also, it comprising at least one robotic arm and a rotated chassis, and it uses said rotated chassis to shift said robotic arm, then, using said robotic arm to pick up said substrate, and therefore, said substrate changing between said multiple chambers.

15. The apparatus of the chemical metal organic vapor epitaxy for the multi-chamber epitaxy layer deposition according to claim 14, wherein the numbers of said chamber is equal to the required reaction time of said first epitaxy layer divide to the required reaction time of said second epitaxy layer, and more, it uses integral part of the number.
